(19) United States
(12) Patent Application Publication
(10) Pub. No.: US 2015/0062852 A1
(43) Pub. Date: Mar. 5, 2015

(54) SEMICONDUCTOR PACKAGES HAVING PASSIVE COMPONENTS AND METHODS FOR FABRICATING THE SAME

(71) Applicant: Samsung Electronics Co., Ltd., Suwon-si (KR)

(72) Inventors: In-Jae LEE, Hwaseong-si (KR); Jin-Young JUNG, Asan-si (KR)

(73) Assignee: Samsung Electronics Co., Ltd., Suwon-si (KR)

(21) Appl. No.: 14/278,835

(22) Filed: May 15, 2014

(30) Foreign Application Priority Data
Aug. 30, 2013 (KR) 10-2013-0104370

(51) Int. Cl. H01L 23/522; H01L 49/02; H05K 1/18; H01L 23/15

(52) U.S. Cl. CPC H01L 23/522; H01L 23/15; H01L 28/60; H05K 1/181
USPC 361/782; 257/693; 257/690

(57) ABSTRACT

Semiconductor packages having through electrodes and methods for fabricating the same are provided. The method for fabricating a semiconductor package may comprise providing a package substrate including a core having a top surface and a bottom surface and a plurality of surface mount pads on the top surface of the core, providing a passive component on the package substrate between the surface mount pads, and forming an electrical connection that fills spaces between the surface mount pads and the passive component provided therebetween and electrically connects the passive component to the package substrate.

### CROSS-REFERENCE TO RELATED APPLICATIONS

This U.S. nonprovisional patent application claims priority under 35 U.S.C. §119 of Korean Patent Application 10-2013-0104370 filed on Aug. 30, 2013, the entire contents of which are hereby incorporated by reference.

### BACKGROUND

The present inventive concept relates to semiconductor and, more particularly, to semiconductor packages having passive components and methods for fabricating the same.

In manufacturing semiconductor packages, passive components such as resistors, inductors, capacitors and so like, as well as semiconductor chips are mounted on a package substrate. Thicknesses of semiconductor chips and passive components may be carefully considered for shrinking sizes of semiconductor packages.

### SUMMARY

Embodiments of the present inventive concept provide semiconductor packages having passive components and methods for fabricating the same in which passive components are mounted on a package substrate between surface mounting lands.

According to exemplary embodiments of the present inventive concepts, a semiconductor package may comprise: a plurality of lands spaced apart from each other on a package substrate; a passive component on the package substrate between the lands; and an electrical connection between a side of the passive component and a corresponding one of the lands.

In some embodiments, the package substrate may comprise: a core including a top surface and a bottom surface; and an insulating layer on the bottom surface.

In some embodiments, the passive component may comprise a capacitor on the core, the capacitor contacting the top surface of the core.

In some embodiments, the passive component may comprise a capacitor on the top surface of the core, and the semiconductor package may further comprise an adhesive layer between the top surface of the core and the capacitor.

In some embodiments, the package substrate may comprises a recess region to receive the passive component, the recess region including a depth less than a thickness of the core and a width substantially identical to or greater than a width of the passive component.

In some embodiments, a distance between the adjacent lands may be substantially identical to or greater than the width of the recess region.

In some embodiments, the capacitor may comprise a multi-layer ceramic capacitor including a ceramic body and electrodes formed on lateral sides of the ceramic body, each electrode corresponding to one of the lands, and the electrical connection may comprise a solder which electrically connects the electrode to the corresponding one of the lands.

In some embodiments, the electrodes may be spaced apart from the corresponding lands, and the solder may fill a space between the electrode and the corresponding land.

In some embodiments, the lands may have a rectangular shape adjacent to the corresponding electrodes, in plan view, or a bracket shape enclosing the corresponding electrodes, in plan view.

In some embodiments, the land may comprise a plurality of sub-electrodes adjacent to the corresponding electrode, the sub-electrodes having a rectangular shape, in plan view, or a bending shape enclosing a corner of the corresponding electrode, in plan view.

According to exemplary embodiments of the present inventive concepts, a method for fabricating a semiconductor package may comprise: providing a package substrate including a core having a top surface and a bottom surface and a plurality of surface mount pads on the top surface of the core; providing a passive component on the package substrate between the surface mount pads; and forming a solder that fills spaces between the surface mount pads and the passive component provided therebetween and electrically connects the passive component to the package substrate.

In some embodiments, before providing of the passive component, forming of the solder may comprise: providing a solder paste on the package substrate, the solder paste partially covering a portion of the surface mount pads; providing the passive component on the solder paste; and reflowing the solder paste.

In some embodiments, after providing of the passive component, forming of the solder may comprise: providing a solder paste on the package substrate, the solder paste covering at least portions of the surface mount pads and at least portions of lateral sides of the passive component; and reflowing the solder paste.

In some embodiments, providing of the passive component may comprise mounting a capacitor including a ceramic body and electrodes on lateral sides of the ceramic body, wherein the capacitor directly contacts the top surface of the core.

In some embodiments, providing of the passive component may comprise: partially removing the top surface of the core between the surface mount pads to form a recess region; and providing a capacitor in the recess region, wherein the capacitor comprises a ceramic body and electrodes on lateral sides of the ceramic body.

### BRIEF DESCRIPTION OF THE DRAWINGS

The foregoing and other features and advantages of exemplary embodiments of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1A is a plan view illustrating a semiconductor package according to exemplary embodiments of the present inventive concepts;

FIG. 1B is a cross-sectional view taken along a line A1-A2 of FIG. 1A;

FIG. 1C is a cross-sectional view of modified example of FIG. 1B;

FIG. 2A is a cross-sectional view illustrating a capacitor included in a semiconductor package according to exemplary embodiments of the present inventive concepts;

FIG. 2B is a plan view illustrating a capacitor included in a semiconductor package according to embodiments of the present inventive concepts;

FIG. 2C is a comparative plan view illustrating a capacitor included in a semiconductor package by way of methods different from those of the present inventive concepts;

FIGS. 3A to 3C are cross-sectional views illustrating surface mount lands of semiconductor packages according to exemplary embodiments of the present inventive concepts.

FIGS. 4A and 4B are cross-sectional views illustrating a method for mounting a capacitor in a semiconductor package according to exemplary embodiments of the present inventive concepts;

FIGS. 4C and 4D are some exemplary embodiments of FIG. 4B.

FIGS. 5A to 5C are cross-sectional views illustrating a method for mounting a capacitor in a semiconductor package according to exemplary embodiments of the present inventive concepts.

FIGS. 6A to 6C are cross-sectional views illustrating a method for mounting a capacitor in a semiconductor package according to exemplary embodiments of the present inventive concepts;

FIGS. 6D to 6F are some exemplary embodiments of FIG. 6C.

FIGS. 7A to 7C are cross-sectional views illustrating a method for mounting a capacitor in a semiconductor package according to exemplary embodiments of the present inventive concepts.

FIGS. 8A and 8B are cross-sectional views illustrating a method for mounting a capacitor in a semiconductor package according to exemplary embodiments of the present inventive concepts;

FIG. 8C is a cross-sectional view of modified embodiment of FIG. 8B; and

FIG. 9 is a schematic block diagram illustrating an example of computing system equipped with a memory card including a semiconductor package according to embodiments of the present inventive concepts.

### DETAILED DESCRIPTION OF PREFERRED EMBODIMENTS

Example embodiments of inventive concepts will now be described more fully hereinafter with reference to the accompanying drawings, in which some example embodiments of inventive concepts are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements. Hereinafter, it will be described about an exemplary embodiment of the present invention in conjunction with the accompanying drawings.

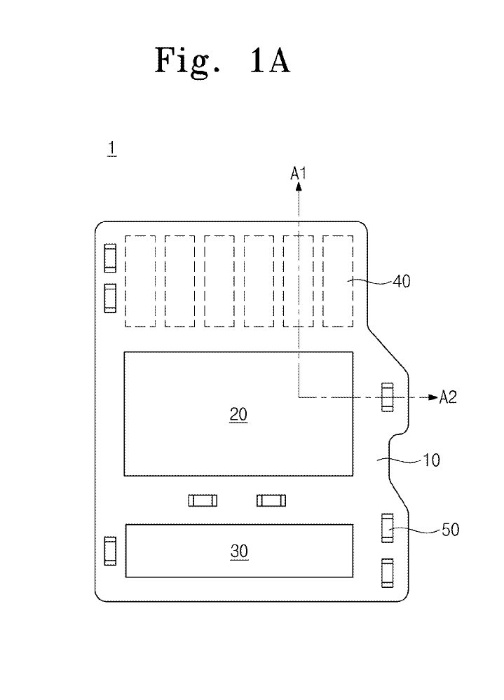

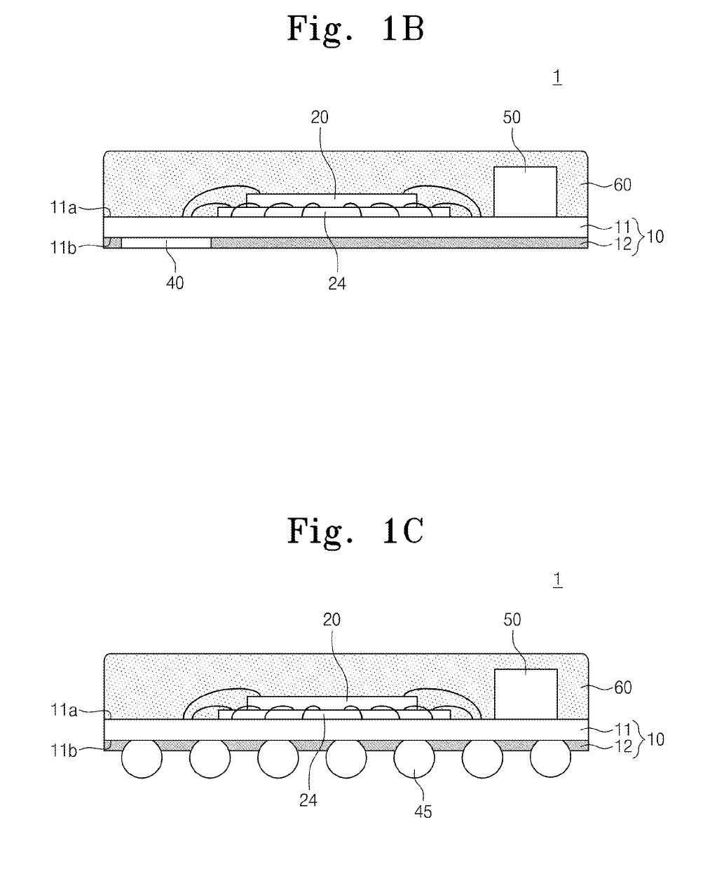

FIG. 1A is a plan view illustrating a semiconductor package or a memory card according to exemplary embodiments of the present inventive concepts. FIG. 1B is a cross-sectional view taken along a line A1-A2 of FIG. 1A. FIG. 1C is a cross-sectional view of modified example of FIG. 1B.

Referring to FIGS. 1A and 1B, a semiconductor package 1 may comprise semiconductor chips 20 and 30 mounted on a package substrate 10. For example, the semiconductor chips 20 and 30 may comprise a semiconductor memory chip 20 and a controller chip 30. The semiconductor package 1 may further comprise at least one pad 40 and at least one passive component 50 such as a capacitor, a resistor, an inductor and so forth.

As shown in FIGS. 1B and 1C, the semiconductor chip 20 may be stacked on another semiconductor chip 24 such as a memory chip.

Capacitors may be shown as ones of the passive components 50 and other components may be omitted for the sake of brevity. A numerical reference 50 may identify the passive component or the capacitor. In addition to the capacitor, the present inventive concepts may also apply to other passive components.

The package substrate 10 may be a printed circuit board including a core 11 (e.g., copper clad laminate) having a top surface 11a and a bottom surface 11b and an insulating layer 12 (e.g., photo solder resist) covering the top surface 11a and/or the bottom surface 11b of the core 11. For example, the insulating layer 12 may be provided on the bottom surface 11b of the core 11 but may be not provided on the top surface 11a of the core 11. The semiconductor chips 20 and 30 and capacitors 50 may be provided on the top surface 11a of the core 11, and the pads 40 may be provided on the bottom surface 11b of the core 11. Instead of the pads 40, other external conductive terminals such as solder balls 95 may be attached to the bottom surface 11b of the core 11 as illustrated in FIG. 1C. A mold layer 60 may be provided to cover the semiconductor chips 20 and 30 and the capacitors 50.

The capacitors 50 may have heights substantially identical to or greater than those of the semiconductor chips 20 and 30. For example, the capacitors 50 may have heights of about 300 nm to about 600 nm, and the semiconductor chips 20 and 30 may have heights identical to or less than those of the capacitors 50. Some of the capacitors 50 may have a lower height (e.g., 300 nm) and others may have a greater height (e.g., 600 nm). Passive components such as resistors and inductors may have heights greater or less than those of the capacitors 50.

The capacitors 50 may be disposed on edge regions of the package substrate 10. Alternatively, the capacitors 50 may be evenly disposed on edge regions and a center region of the package substrate 10.

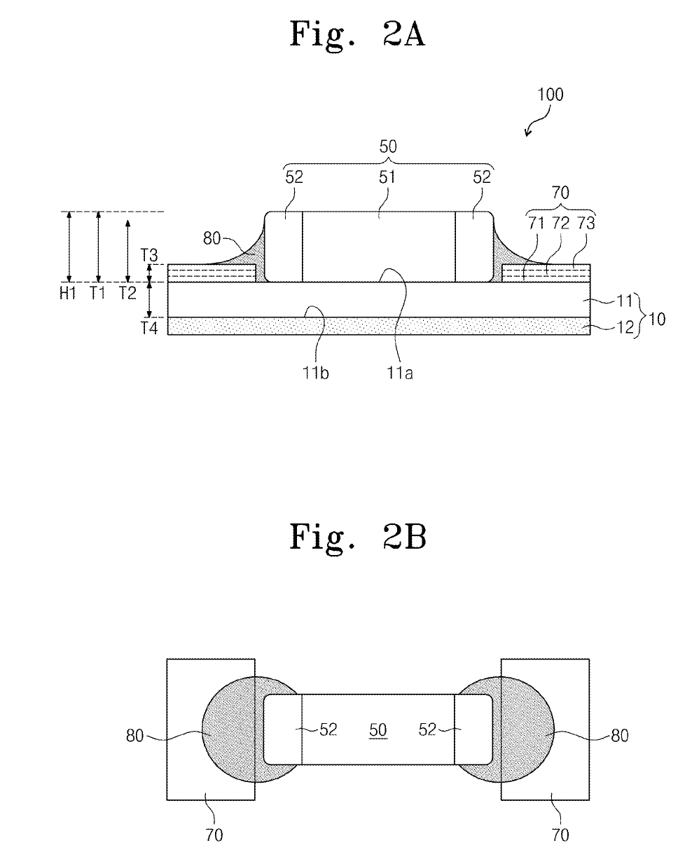

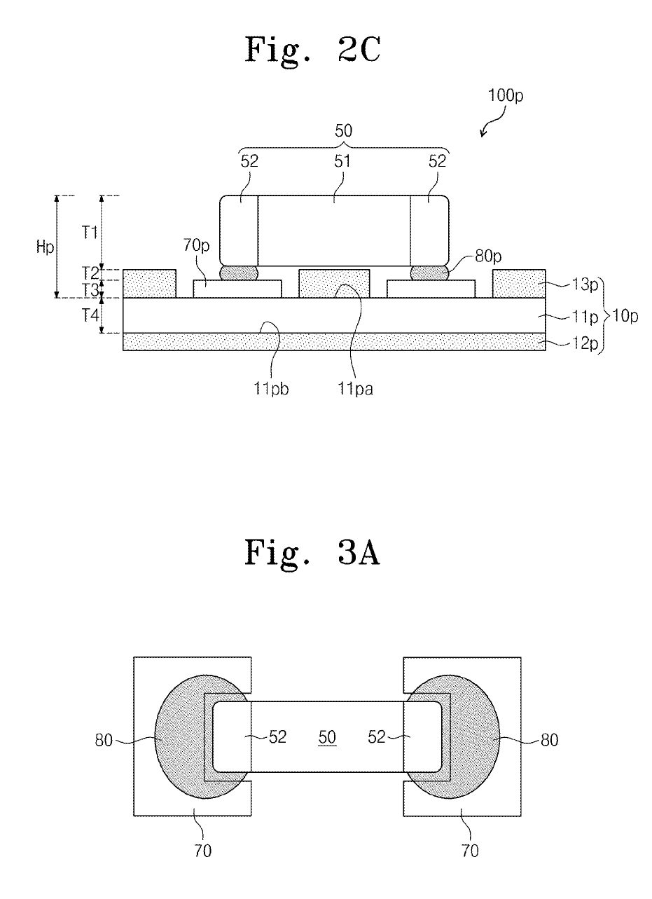

FIG. 2A is a cross-sectional view illustrating a capacitor included in a semiconductor package according to exemplary embodiments of the present inventive concepts. FIG. 2B is a plan view illustrating a capacitor included in a semiconductor package according to some embodiments of the present inventive concepts. FIG. 2C is a comparative plan view illustrating a capacitor included in a semiconductor package by way of methods different from those of the present inventive concepts.

Referring to FIGS. 2A and 2B, the capacitor 50 may be a multi-layer ceramic capacitor (MLCC) including a ceramic body 51 and electrodes 52 on opposite sides (or ends) of the ceramic body 51. The capacitor 50 may be electrically connected to the package substrate 10 via solders 80 provided between the electrodes 52 and surface mounted lands 70. The solder 80 may comprise a lead-free solder such as Sn, Sn—Ag and so forth.

The land 70 may comprise a single-layered or multi-layered conductor. For example, the land 70 may comprise a first conductive layer 71 formed of a conductive material such as Cu, a third conductive layer 73 formed of a conductive material such as Au and a second conductive layer 72 formed of a conductive material such as Ni interposed between the first conductive layer 71 and the third conductive layer 73. The third conductive layer 73 may be provided to prevent oxidation of the land 70 and ensure good electrical contacts between the land 70 and the solder 80. The second conductive layer 72 may be provided to prevent constituents (e.g., Cu and Au) of the first and third conductive layers 71 and 73 from mixing with each other. The land 70 may have a rectangular shape spaced apart from the electrode 52, in plan view.

In some embodiments, the capacitor 50 may be provided between the lands 70. The capacitor 50 need not be provided on the lands 70, depending on the application. For example, the capacitor 50 may be mounted on the package substrate 10 between the lands 70, thereby contacting with the top surface 11a of the core 10.

Because the land 70 is provided on the core 11 between the lands 70, the capacitor 50 and the lands 70 may configure an electrical connection structure 100 having a height H1 that substantially corresponds to a thickness T1 of the capacitor 50. In other words, even though the solder 80 has a thickness T2 substantially identical to or less than the thickness T1 of the capacitor 50, the thickness T2 of the solder 80 may not increase the height H1 of the electrical connection structure 100 because the solder 80 is provided between the land 70 and the capacitor 50. Furthermore, the capacitor 50 may not be disposed on the land 70 such that a thickness T3 of the land 70 may not increase the height H1 of the electrical connection structure 100. The land 70 may have a thickness T3 of about 10 nm to about 50 nm. The core 11 may have a thickness T4 of about 100 nm.

The thickness T2 of the solder 80 and the thickness T3 of the land 70 may not increase the height H1 of the electrical connection structure 100 such that the thicknesses T2 and T3 may be ignored when the capacitor 50 is mounted on the package substrate 10.

In the specification of the present application, the height H1 of the electrical connection structure 100 may mean a distance from the top surface 11a of the core 11 to a top surface of the capacitor 50.

If the capacitor 50 is provided on the core 11, the height H1 of the electrical connection structure 100 may be reduced such that a height of the semiconductor package 1 may be decreased compared to a case where the capacitor 50 is provided on the lands 70. This will be explained in detail with reference to FIG. 2C.

Referring to FIG. 2C, when the capacitor 50 is provided on lands 70p different than a case where the capacitor 50 is provided on a core 11p, solders 80p may be provided between top surfaces of the lands 70p and bottom surfaces of the electrodes 52. Similar to a case where an insulating layer 12p is provided on a bottom surface 11pb of the core 11p, another insulating layer 13p may be further provided on a top surface 11pa of a core 11p. The lands 70p and the capacitor 50 may constitute an electrical connection structure 100p having a height Hp corresponding to a sum total of the thickness T1 of the capacitor 70, the thickness T2 of the solder 80p and the thickness T3 of the land 70p. Compared to the electrical connection structure 100p, having a height Hp, the electrical connection structure 100 of FIG. 2A may have the height H1 reduced by at least the thickness T3 of the land 70.

In some embodiments, the electrical connection structure 100 may be relatively unaffected by the thickness T1 of the capacitor 50, unlike in the electrical connection structure 100p. For example, as illustrated in FIG. 2C, since the thickness T2 of the solder 80p and the thickness T3 of the land 70p may contribute the height Hp of the electrical connection structure 100p, it may be difficult to fabricate a thin semiconductor package inclusive of the capacitor 50 having a relatively large thickness, for example, about 600 nm or more. According to some embodiments, the thickness T2 of the solder 80 and the thickness T3 of the land 70 may not contribute the height H1 of the electrical connection structure 100 as illustrated in FIG. 2A. Consequently, the capacitor 50 having a relatively large thickness can be used to fabricate a thin semiconductor package.

In some embodiments, the solder 80 may have a shape substantially surrounding a lateral edge region of the electrode 52 as illustrated in FIG. 2B. In the comparative embodiment, as illustrated in FIG. 2C, the solder 80p may contact only a limited portion of the bottom surface of the electrode 52. A contact area between the solder 80 and the electrode 52 of FIG. 2A may be greater than a contact area between the solder 80p and the electrode 52 of FIG. 2C. Therefore, the electrical connection structure 100 may a superior electrical connection between the capacitor 50 and the package substrate 10.

The electrical connection structure 100 may have various configurations different from that of FIG. 2A, which will be explained in detail later.

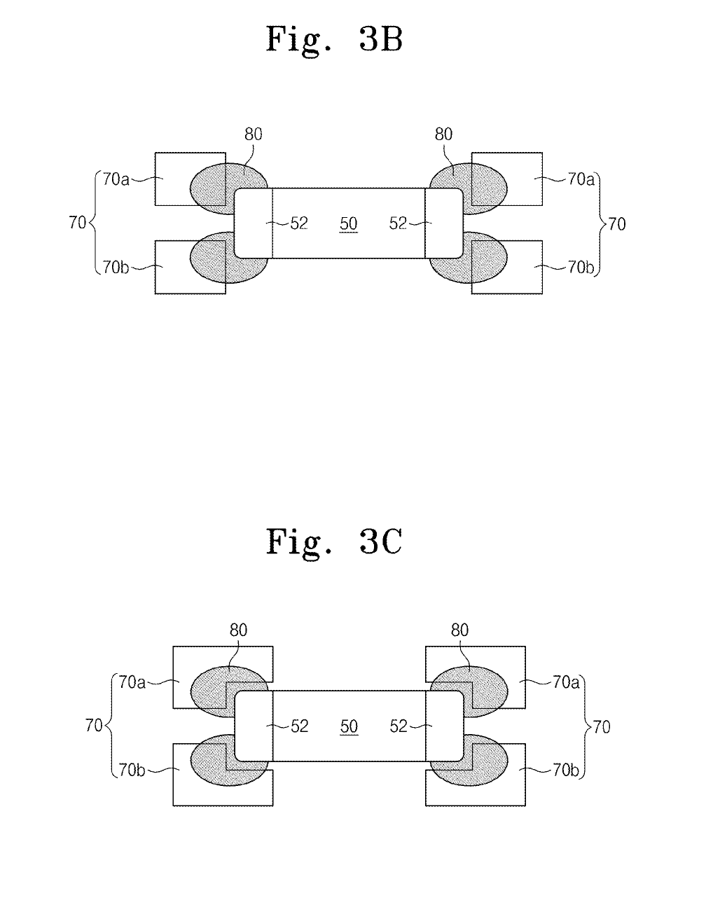

FIGS. 3A to 3C are cross-sectional views illustrating surface mount lands of semiconductor packages according to some other exemplary embodiments of the inventive concepts.

Referring to FIG. 3A, the land 70 may have a bracket shape substantially surrounding the electrode 52 of the capacitor 50. A contact area between the solder 80 and the land 70 may be increased such that a good electrical contact is made between the capacitor 50 and the land 70. When the volumes and/or the surface tensions of the solders 80 are different from each other, the capacitor 50 may move laterally so that an electrical connection between the capacitor 50 and the lands 72 may become poor. Even though the solders 80 have different volume and/or surface tension, the bracket shape of the land 70 may secure a good electrical connection between the land 70 and the electrode 52.

Referring to FIG. 3B, the land 70 may comprise a first sub-land 70a and a second sub-land 70b adjacent to corners of the electrode 52. The first and second sub-lands 70a and 70b may have a rectangular shape in plan view. In some embodiments, even the volumes and/or the surface tensions of the solders 80 are different from each other, the first and second sub-lands 70a and 70b may make good electrical contacts with the electrodes 52. For example, even though the electrode 52 may have a poor electrical connection with the first sub-land 70a, the electrode 52 may still have a good contact with the second sub-land 70b such that the capacitor 50 may still have a good electrical connection with the lands 70. The number of the sub-lands 70a and 70b may be two or more.

Referring to FIG. 3C, the land 70 may comprise first and second sub-lands 70a and 70b each having a bent shape such as “L”-shape in plan view. The L-shaped first and second sub-lands 70a and 70b may substantially surround corners of the electrode 52 to increase contact areas between the solder 80 and the sub-lands 70a and 70b and between the solder 80 and the electrodes 52, thereby ensuring good electrical connections between the capacitor 50 and the lands 70. Furthermore, even the volumes and/or the surface tensions of the solders 80 are different from each other, the first and second sub-lands 70a and 70b may have good electrical connections with the electrodes 52.

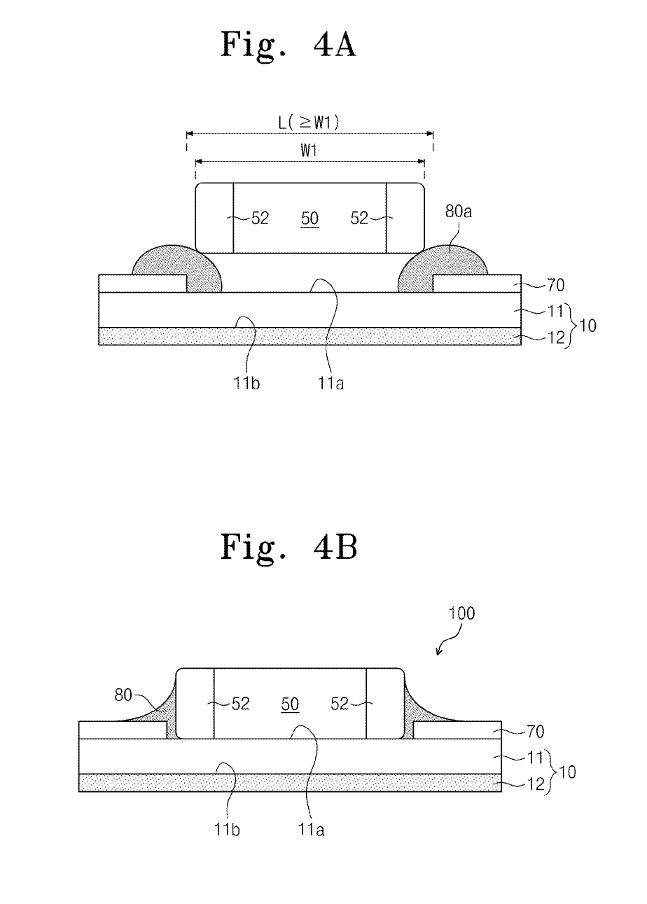

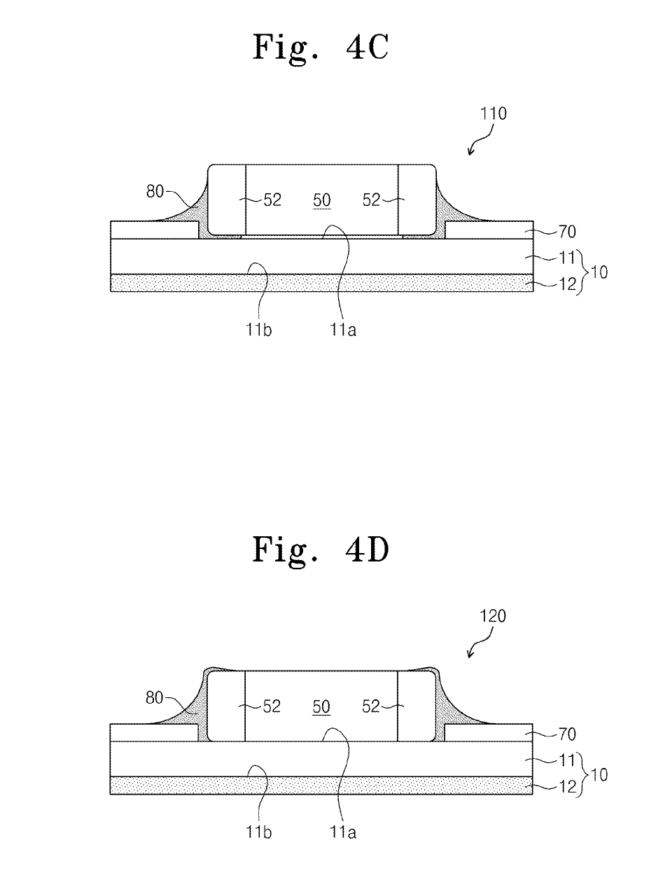

FIGS. 4A and 4B are cross-sectional views illustrating a method for mounting a capacitor in a semiconductor package according to some embodiments of the present inventive concepts. FIGS. 4C and 4D are some exemplary embodiments of FIG. 4B.

Referring to FIG. 4A, solder pastes 80a may be provided on the package substrate 10 having the lands 70 formed thereon. The solder pastes 80a may be provided on the lands 70 and the capacitor 50 may be placed on the solder pastes 80a. Alternatively, the solder pastes 80a may be provided on both the lands 70 and the core 11. In some embodiments, a distance L between the lands 70 may be greater than a width W1 of the capacitor 50.

Referring to FIG. 4B, a reflow process may be performed where the capacitor 50 is placed on the solder pastes 80a. In the reflow process, the solder pastes 80a may be liquefied and the capacitor 50 may descend onto the core 11, e.g., a top surface of the package substrate 10. In some embodiments, the capacitor 50 may directly contact the top surface 11a of the core 11. The solder paste 80a may be reflowed to form the solder 80 that fills a space between the land 70 and the electrode 52 such that the solder 80 may electrically connect the capacitor 50 to the lands 70. As a result, the solder 80 may electrically connect the capacitor 50 to the package substrate 10. The solder 80 may partially or completely cover a top surface of the land 70 and fill the space between the land 70 and the electrode 52. The solder 80 may further partially or entirely cover a sidewall of the electrode 52. Through the above-mentioned processes, the electrical connection structure 100 in which the capacitor 50 is disposed on the top surface 11a of the core 11 (or the top surface of the package substrate 10) may be formed between the lands 70.

Alternatively, as illustrated in FIG. 4C, an electrical connection structure 110 in which the solder 80 is further disposed between the electrode 52 and the core 11 may be formed. The capacitor 50 may not directly contact the top surface 11a of the core 11. Thus, a gap may exist between the top surface 11a of the core 11 or the top surface of the package substrate 10.

Alternatively, as illustrated in FIG. 4D, an electrical connection structure 120 in which the solder 80 extends over a portion of the electrode 52 may be formed. The extension of the solder 80 may increase the contact area between the capacitor 50 and the land 70. The capacitor 50 may directly contact the top surface 11a of the core 11. Identical or similar to FIG. 4C, the solder 80 may further fit within a gap between the electrode 52 and the core 11 such that the capacitor 50 may not directly contact the top surface 11a of the core 11.

Referring to FIGS. 1B and 4B, the capacitor 50 may be mounted before or after the semiconductor chips 20 and 30 are mounted on the package substrate 10. The semiconductor package 1 may be fabricated by forming the mold layer 60 that covers passive components including the capacitor 50 and the semiconductor chips 20 and 30 mounted on the package substrate 10.

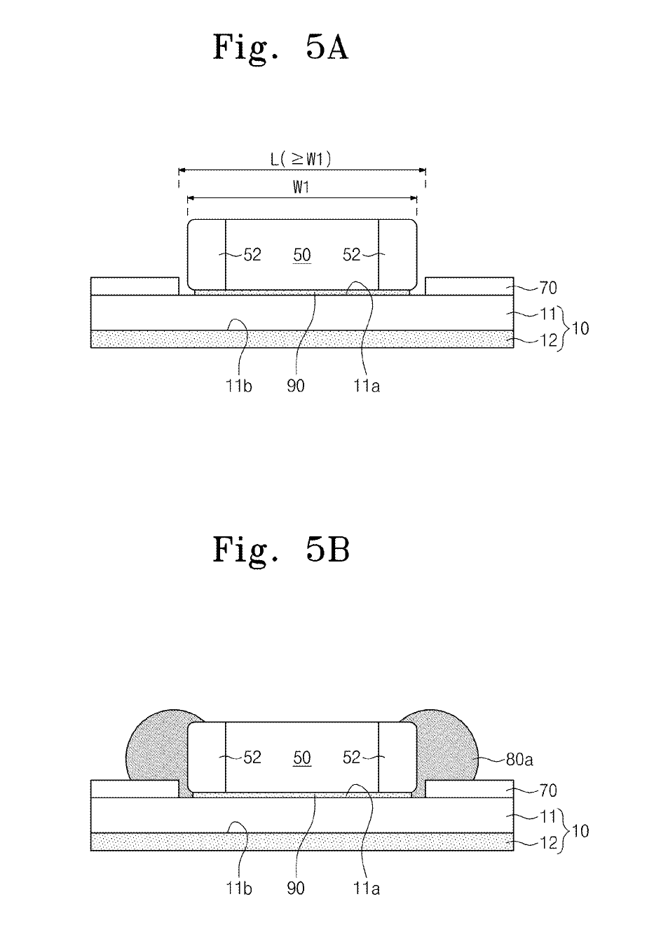

FIGS. 5A to 5C are cross-sectional views illustrating a method for mounting a capacitor in a semiconductor package according to exemplary embodiments of the present inventive concepts.

Referring to FIG. 5A, the capacitor 50 may be provided on the core 11 (or the package substrate 10) between the lands 70. An insulating glue layer 90 may be further provided between the capacitor 50 and the core 11 (or the package substrate 10) to firmly adhere the capacitor 50 to the package substrate 10. The distance L between the lands 70 may be substantially identical to or greater than the width W1 of the capacitor 50. For the sake of brevity, the distance L may be shown greater than the width W1.

Referring to FIG. 5B, the solder pastes 80a may be provided on the package substrate 10 to which the capacitor 50 is adhered. The solder paste 80a may be provided on the land 70 and the capacitor 50. The reflow process may be performed after the solder paste 80a is provided.

Referring to FIG. 5C, the solder paste 80a may be liquefied or reflowed to form the solder 80 which fills a gap between the land 70 and the electrode 52, thereby electrically connecting the capacitor 50 to the lands 70. Through the above-mentioned processes, an electrical connection structure 130 in which the capacitor 50 is adhered to the core 11 (or the package substrate 10) between the lands 70 may be formed. The solder 80 of the electrical connection structure 130 may further extend over a portion of the electrode 52, as illustrated in FIG. 4D.

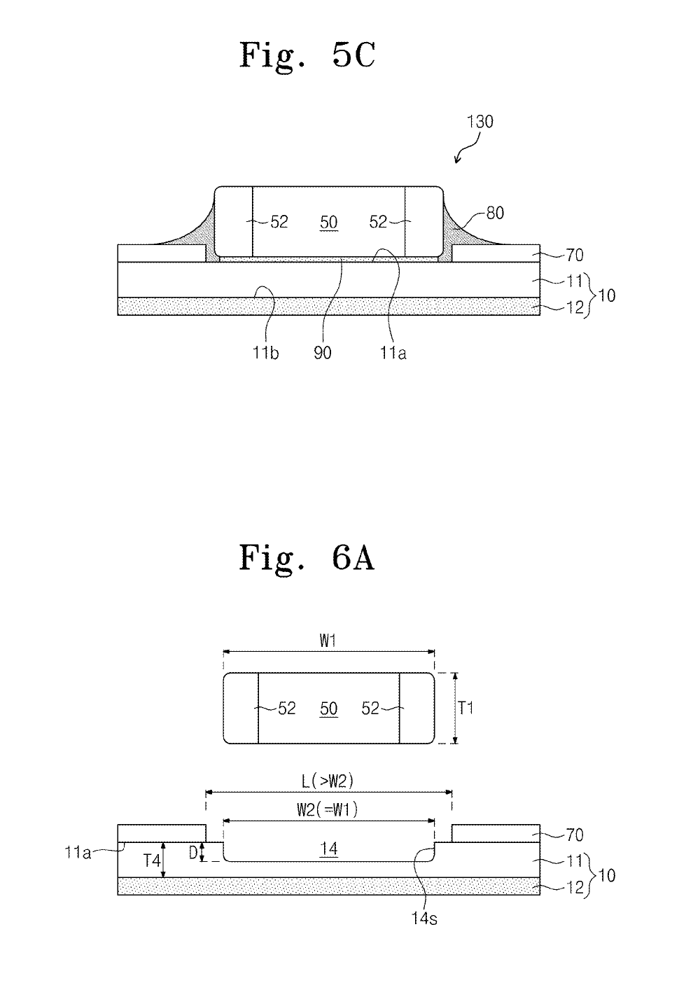

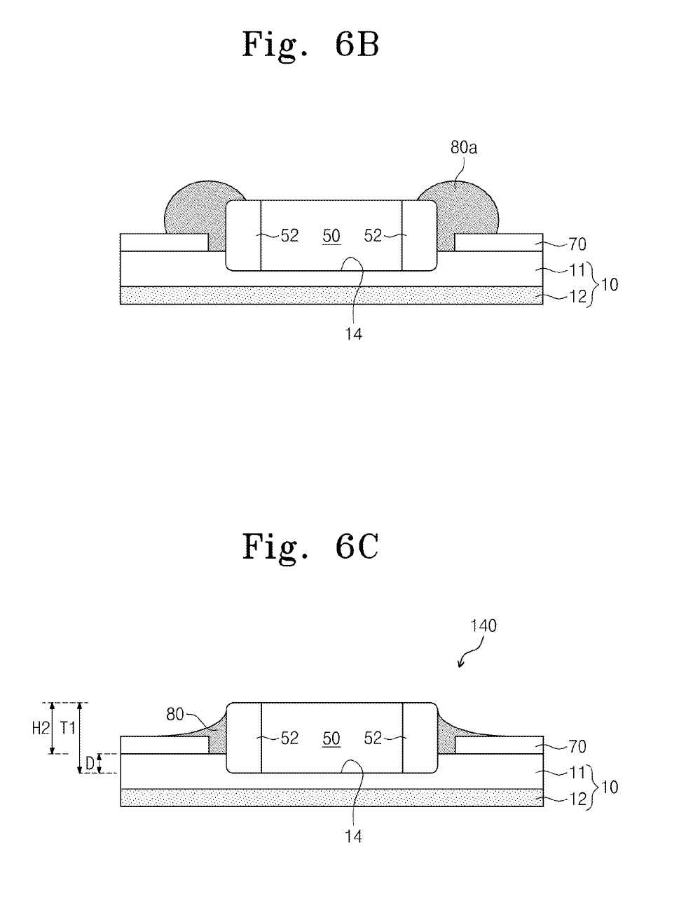

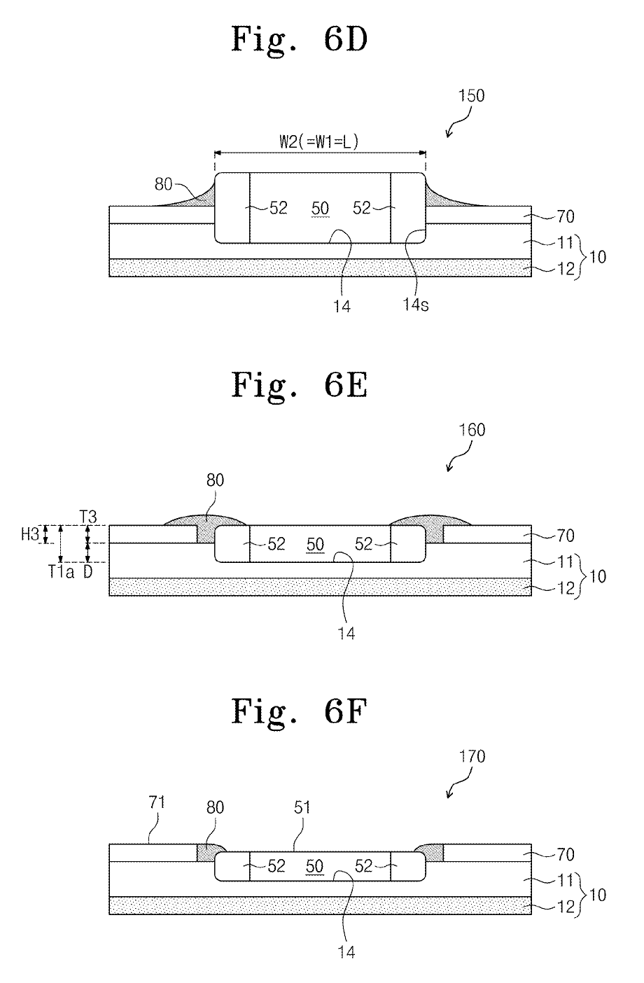

FIGS. 6A to 6C are cross-sectional views illustrating a method for mounting a capacitor in a semiconductor package according to some other embodiments of the present inventive concepts. FIGS. 6D and 6F are some exemplary embodiments of FIG. 6C.

Referring to FIG. 6A, the package substrate 10 may comprise a recess region 14 formed by partially etching the top surface 11a of the core 11 (or the package substrate 10). The recess region 14 may have a width W2 substantially identical to the width W1 of the capacitor 50 and a depth D that is less than the thickness T4 of the core 11. For example, the recess region 14 may have inner sidewalls 14s that do not extend to the lands 70.

Referring to FIG. 6B, the capacitor 50 may be inserted into the recess region 14 and thereafter the solder paste 80a may be provided. The solder paste 80a may be provided on the land 70 and the capacitor 50 to fill a gap between the land 70 and the electrode 52. In some embodiments, the capacitor 50 may be rigidly settled within the recess region 14 without the help of adhesive.

Referring to FIG. 6C, the solder paste 80a may be reflowed to form the solder 80 to electrically connect the land 70 to the electrode 52. Through the above-mentioned processes, an electrical connection structure 140 having a height H2 less than the thickness T1 of the capacitor 50 may be formed. In some embodiments, the height H2 may correspond to a length subtracting the depth D of the recess region 14 from the thickness T1 of the capacitor 50, i.e., H2=T1−D. The solder 80 may further extend over the electrode 52, as illustrated in FIG. 4D.

Alternatively, as illustrated in FIG. 6D, an electrical connection structure 150 may be formed to include the recess region 14 having the width W2 that is substantially identical to both the width W1 of the capacitor 50 and the length L between the lands 70. The recess region 14 may have inner sidewalls 14s substantially coplanar with the inner sidewalls of the lands 70. The capacitor 50 may be inserted into the recess region 14 such that the electrodes 52 directly contact the inner sidewalls of the lands 70 and electrically connected thereto through the solders 80. In some embodiments, the solder 80 may occupy a corner area where the electrode 52 meets the land 70 at an angle of about 90°.

Alternatively, as illustrated in FIG. 6E, an electrical connection structure 160 may be fabricated to include the capacitor 50, which has a thickness T1a insufficient to extend above a height of the land 70, inserted in the recess region 14. For example, the thickness T1a of the capacitor 50 may be substantially the same as or less than a sum total (i.e., T3+D) of the thickness T3 of the land 70 and the depth D of the recess region 14. The electrical connection structure 160 may have a height H3 same as or less than the thickness T3 of the land 70.

In some embodiments, as shown in FIG. 6F, a top surface 51 of the capacitor 50 may be lower than a top surface 71 of the land 70. As a result, an overall thickness of the semiconductor package 1 or an electrical connection structure 170 may be reduced.

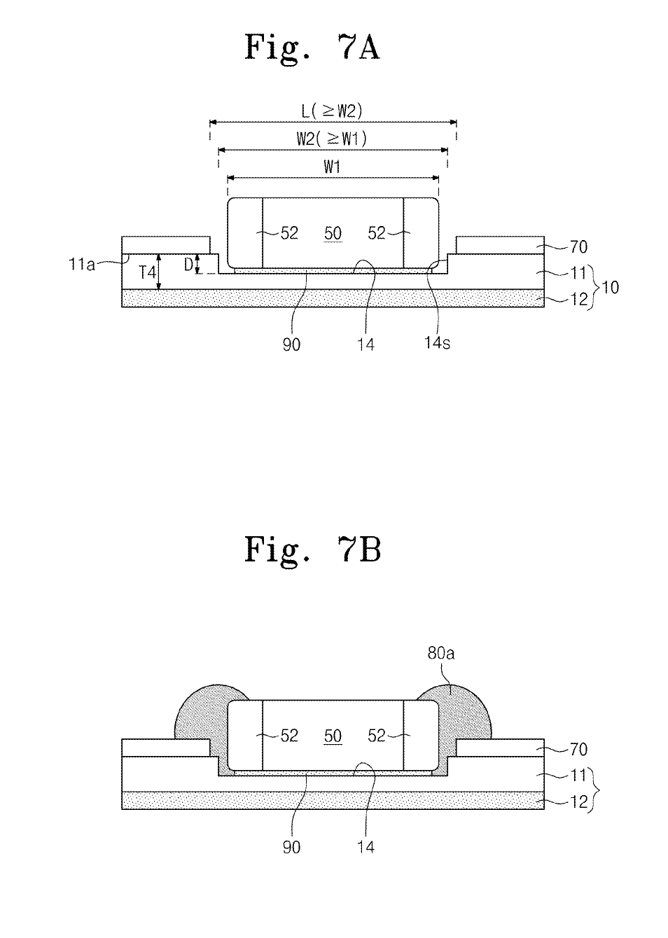

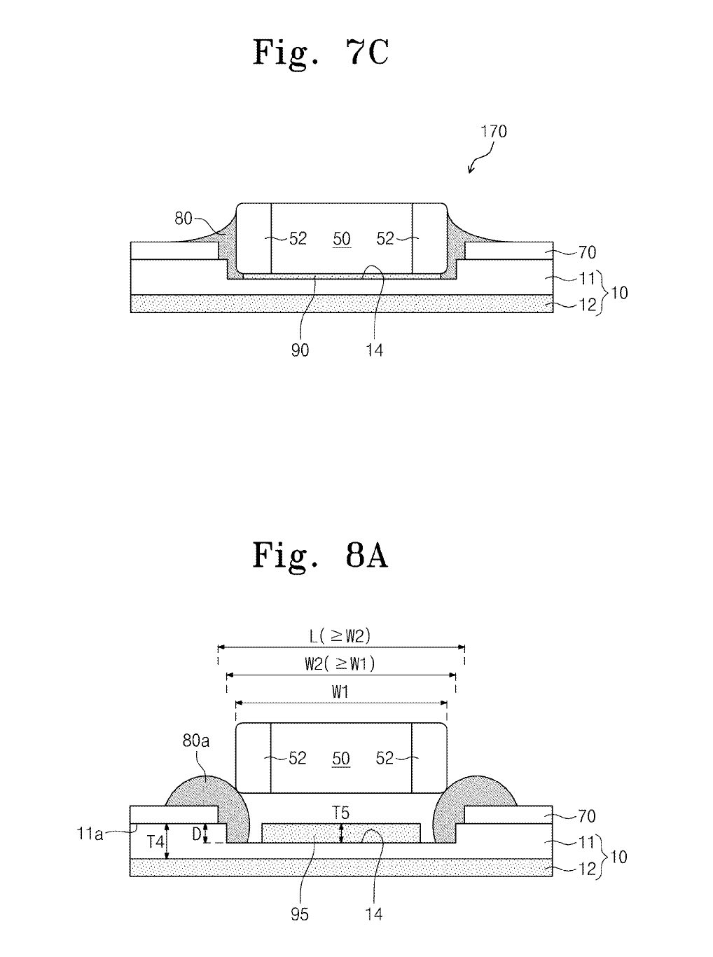

FIGS. 7A to 7C are cross-sectional views illustrating a method for mounting a capacitor in a semiconductor package according to some embodiments of the present inventive concepts.

Referring to FIG. 7A, the package substrate 10 may comprise the recess region 14 formed by partially etching the top surface 11a of the core 11 (or the package substrate 10). The capacitor 50 may be provided within the recess region 14 between the lands 70. The insulating glue layer 90 may be further provided between the capacitor 50 and the core 11 (or the package substrate 10) so as to firmly adhere the capacitor 50 to the package substrate 10.

The recess region 14 may have a width W2 that is the same as or greater than the width W1 of the capacitor 50 and the depth D less than the thickness T4 of the core 11. The distance L between the lands 70 may be the same as or greater than the width W2 of the recess region 14. For example, the width W2 of the recess region 14 may be greater than the width W1 of the capacitor 50. The distance L between the lands 70 may be greater than the width W2 of the recess region 14, so that each of the inner sidewalls 14s of the recess region 14 may not reach the land 70.

Referring to FIG. 7B, the solder pastes 80a may be provided on the package substrate 10 to which the capacitor 50 is attached. The solder paste 80a may be provided on the land 70 and the capacitor 50. The reflow process may be performed after the solder paste 80a is provided.

Referring to FIG. 7C, the solder paste 80a may be liquefied to form the solder 80 which fills a gap between the land 70 and the electrode 52, thereby electrically connecting the capacitor 50 to the lands 70. Through the above-mentioned processes, an electrical connection structure 170 in which the capacitor 50 is inserted in the recess region 14 and adhered to the core 11 by the glue layer 90 may be formed. The solder 80 may further extend over the electrode 52, as illustrated in FIG. 4D.

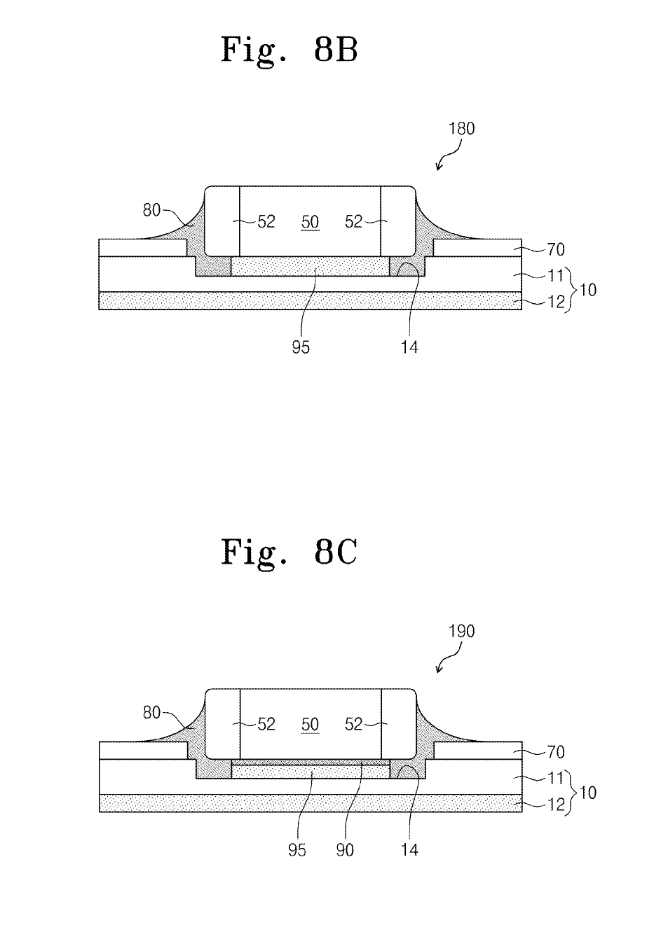

FIGS. 8A and 8B are cross-sectional views illustrating a method for mounting a capacitor in a semiconductor package according to some embodiments of the present inventive concepts. FIG. 8C is a cross- section view illustrating modified exemplary embodiment of FIG. 8B.

Referring to FIG. 8A, the package substrate 10 may comprise the recess region 14 formed by partially etching the top surface 11a of the core 11 (or the package substrate 10). The recess region 14 may include a blocking wall 95 formed therein. The blocking wall 95 may comprise an insulator identical or similar to that of the insulating layer 12, and have a thickness T5 the same as or less than the depth D of the recess region 14. The solder pastes 80a may be provided on the package substrate 10, and the capacitor 50 may be provided on the solder pastes 80a.

The recess region 14 may have the width W2, which is the same as or greater than the width W1 of the capacitor 50 and the depth D less than the thickness T4 of the core 11. The distance L between the lands 70 may be the same as or greater than the width W2 of the recess region 14. For example, the width W2 of the recess region 14 may be greater than the width W1 of the capacitor 50, and the distance L between the lands 70 may be greater than the width W2 of the recess region 14.

Referring to FIG. 8B, the reflow process may be performed where the capacitor 50 is placed on the solder pastes 80a. In the reflow process, the solder pastes 80a may be liquefied and the capacitor 50 may descend down onto the blocking wall 95. In some embodiments, the capacitor 50 may directly contact the blocking wall 95. The solder 80 may fill a space between the land 70 and the electrode 52 and fit within the recess region 14. The solder 80 in the recess region 14 may contact with the lower surface of the electrode 52 such that a contact area between the solder 80 and the electrode 52 may be increased. The blocking wall 95 may prevent a contact between the left and right solders 80, which suppresses an electrical short between the lands 70. Through the above-mentioned processes, the electrical connection structure 180 in which the capacitor 50 is disposed on the blocking wall 95 in the recess region 14 and disposed between the lands 70 may be formed. The solder 80 may further extend over a portion of the electrode 52, as illustrated in FIG. 4D.

Alternatively, an electrical connection structure 190 in which the capacitor 50 is adhered to the blocking wall 95 by the glue layer 90 may be formed. For example, the capacitor 50 may be placed on the blocking wall 95 using the glue layer 90, and thereafter the solder pastes 80a may be provided and reflowed to form the electrical connection structure 190.

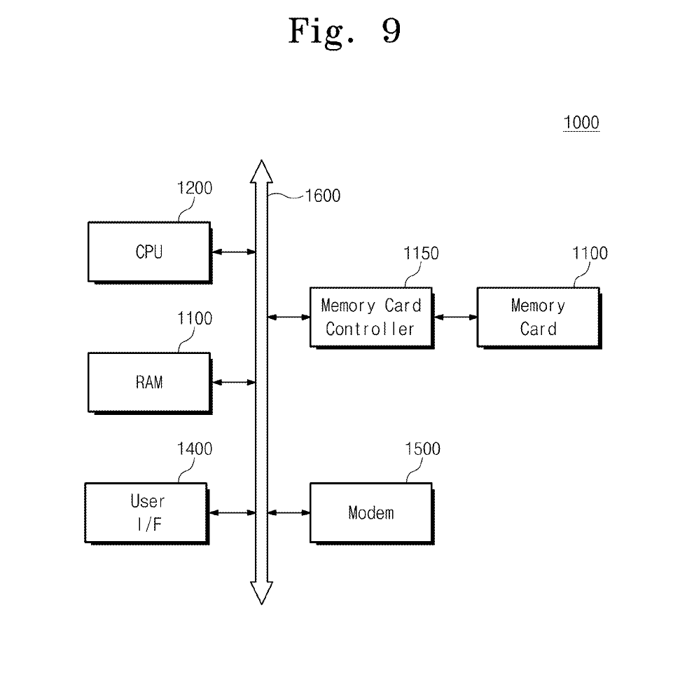

FIG. 9 is a schematic block diagram illustrating an example of computing system equipped with a memory card including a semiconductor package according to embodiments of the present inventive concepts.

Referring to FIG. 9, a computing system 1000 may comprise a central processing unit 1200 such as a microprocessor, a RAM 1300, a user interface 1400, a modem 1500 such as a baseband chipset, and a store medium such as a memory card controller 1150 and a memory card 1100 which are electrically connected to each other by a bus 1600. The memory card 1100 may comprise a semiconductor package 1 which includes at least one of the electrical connection structures 100 to 190 according to some embodiment of the present inventive concepts.

If the computing system 1000 is a mobile apparatus, a battery may be further provided to supply voltage capable of operating the computing system 1000. The computing system 1000 may be further provided with an application chipset, a camera image sensor, a mobile DRAM, etc.

According to some embodiments of the present inventive concepts, passive components such as a capacitor are mounted on a core between surface mount lands, which results in shrinkage of the height of electrical connection as well as the height of the semiconductor package. Furthermore, because the thickness limitation of passive component can be eliminated or reduced, it is accomplished to freely select passive components regardless of thickness, capacitor, number, etc.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A semiconductor package comprising:
a pair of adjacent lands spaced apart from each other on a package substrate;
a passive component on the package substrate between the pair of adjacent lands; and
an electrical connection between a side of the passive component and a corresponding one of the lands.

2. The semiconductor package of claim 1, wherein the package substrate comprises:
a core having a top surface and a bottom surface; and
an insulating layer on the bottom surface.

3. The semiconductor package of claim 2, wherein the passive component comprises a capacitor contacting the top surface of the core.

4. The semiconductor package of claim 2, wherein the passive component comprises a capacitor on the top surface of the core, and wherein the semiconductor package further comprises an adhesive layer between the top surface of the core and the capacitor.

5. The semiconductor package of claim 2, wherein the package substrate comprises a recess region to receive the passive component, the recess region including a depth less than a thickness of the core and a width substantially identical to or greater than a width of the passive component.

6. The semiconductor package of claim 5, wherein a distance between the adjacent lands is substantially identical to or greater than the width of the recess region.

7. The semiconductor package of claim 1, wherein the capacitor comprises a multi-layer ceramic capacitor including a ceramic body and electrodes formed on lateral sides of the ceramic body, each electrode corresponding to one land in the pair of adjacent lands, and
wherein the electrical connection comprises a solder which electrically connects the electrode to the corresponding one of the lands.

8. The semiconductor package of claim 7, wherein the electrodes are each spaced apart from the corresponding one of the lands, and the solder fills a space between the electrode and the corresponding one of the lands.

9. The semiconductor package of claim 7, wherein each land in the pair of adjacent lands has a rectangular shape arranged adjacent to the corresponding electrode, in plan view, or a bracket shape substantially enclosing the corresponding electrode, in plan view.

10. The semiconductor package of claim 7, wherein at least one land in the pair of adjacent lands comprises a plurality of sub-electrodes arranged adjacent to the corresponding electrode.

11. The semiconductor package of claim 10, wherein the sub-electrodes have a rectangular shape, in plan view.

12. The semiconductor package of claim 10, wherein the sub-electrodes have a bent shape substantially surrounding a corner of the corresponding electrode, in plan view.

13. The semiconductor package of claim 10, wherein the plurality of sub-electrodes are spaced apart from each other.

14. A memory card comprising:
a substrate having adjacent lands;
a passive component on the substrate, the passive component disposed between the adjacent lands; and
an electrical connection structure disposed between a sidewall of the passive component and a corresponding one of the adjacent lands,
wherein a substantial portion of the passive component directly contacts a top surface of the substrate.

15. The memory card of claim 14, wherein the passive component and the adjacent lands are laterally spaced apart from each other.

16. The memory card of claim 14, wherein the passive component and the adjacent lands do not overlap with each other.

17. The memory card of claim 14, wherein the passive component comprises a body and electrodes formed on opposite sides of the body, and wherein the solder does not substantially extend between a bottom surface of the body and the top surface of the substrate.

18. The memory card of claim 14, wherein a top surface of the adjacent lands is higher than a top surface of the passive component.

19. A semiconductor package comprising:
a package substrate including a core having a top surface and a bottom surface and a plurality of surface mount pads on the top surface of the core;
a passive component on the package substrate between the surface mount pads; and
a solder that fills spaces between the surface mount pads and the passive component provided therebetween and electrically connects the passive component to the package substrate.

20. The semiconductor package of claim 19, wherein the solder covers at least portions of the surface mount pads and at least portions of lateral sides of the passive components.
